(19) United States
(12) Patent Application Publication
(10) Pub. No.: US 2011/0233546 A1
(43) Pub. Date: Sep. 29, 2011

(54) WAFER-TYPE TEMPERATURE SENSOR AND MANUFACTURING METHOD THEREOF

(75) Inventors: Koudai Higashi, Nirasaki (JP); Masato Hayashi, Nirasaki (JP); Hisaki Ishida, Nirasaki (JP)

(73) Assignee: TOKYO ELECTRON LIMITED, Tokyo (JP)

(21) Appl. No.: 13/053,473

(22) Filed: Mar. 22, 2011

(30) Foreign Application Priority Data
Mar. 23, 2010 (JP) 2010-065789
Feb. 10, 2011 (JP) 2011-026918

(51) Int. Cl. H01L 29/66; H01L 21/50

(52) U.S. Cl. 257/48; 438/55; 257/E29.347; 257/E21.499

(57) ABSTRACT

A wafer-type temperature sensor may include a wafer for temperature detection; a circuit board bonded to one surface of the wafer for temperature detection; at least one temperature data detector provided on the one surface of the wafer for temperature detection and capable of detecting temperature data; and a temperature detecting unit mounted on the circuit board and capable of detecting a temperature of the wafer for temperature detection from the temperature data detected by the temperature data detector. Here, a difference between a linear expansion coefficient of the circuit board and a linear expansion coefficient of the wafer for temperature detection may be equal to or less than a predetermined value.

### CROSS-REFERENCE TO RELATED APPLICATION

This application claims the benefit of Japanese Patent Application Nos. 2010-065789 and 2011-026918 filed on Mar. 23, 2010 and Feb. 10, 2011, respectively, the entire disclosures of which are incorporated herein by reference.

### FIELD OF THE INVENTION

The present disclosure relates to a wafer-type temperature sensor and a manufacturing method thereof.

### BACKGROUND OF THE INVENTION

A semiconductor device such as a LSI (Large Scale Integrated circuit) or a MOS (Metal Oxide Semiconductor) transistor is manufactured by performing various processes such as photolithography, etching, CVD (Chemical Vapor Deposition), sputtering and the like on a wafer as a processing target substrate. By way of example, a processing method using plasma as an energy source, i.e., plasma etching, plasma CVD or plasma sputtering may be used to perform the etching, the CVD or the sputtering process.

A general plasma processing apparatus used in the etching process or the like may include a processing chamber configured to perform a process therein; and a mounting table configured to hold a wafer thereon within the processing chamber. After a wafer is held on the mounting table, an etching process or a CVD process is performed on the wafer by using plasma generated within the processing chamber. A temperature control device such as a heater for controlling a temperature of the wafer held on the mounting table is provided within the mounting table. During the process, the temperature of the wafer is regulated by the temperature control device to an appropriate temperature required for the process. When the etching process or the CVD process is being performed, in order to achieve process uniformity in the surface of the wafer, for example, to achieve process uniformity both in a central area and in a periphery area of the wafer having a circular plate shape, it is important to precisely control a temperature at each position on the wafer during the process. Further, not only such a temperature control during the process but a temperature control during a transfer of the wafer is also important. In this regard, Japanese Patent Laid-open Publication No. 2005-156314 (Patent Document 1) or Japanese Patent Laid-open Publication No. 2007-187619 (Patent Document 2) discloses a technology related to a wafer-type temperature sensor for detecting a temperature of the wafer.
Patent Document 1: Japanese Patent Laid-open Publication No. 2005-156314
Patent Document 2: Japanese Patent Laid-open Publication No. 2007-187619

In accordance with Patent Document 1 or Patent Document 2, a temperature measuring device as a wafer-type temperature sensor includes a temperature detecting unit for detecting a temperature of a wafer as a measurement target object; and a light receiving unit as a data processing device. The temperature detecting unit includes a controller and a temperature sensor mounted on a flexible substrate. The flexible substrate is mounted on a wafer which is processed by plasma within a chamber, i.e., within a processing vessel. The temperature detecting unit converts detected temperature data to an optical pulse signal and transmits the converted signal. The light receiving unit of the temperature measuring device is provided at a position spaced apart from the temperature detecting unit, and the light receiving unit receives the optical pulse signal and decodes it into the temperature data.

In this way, such a configuration for transmitting the temperature data measured by the wafer-type temperature sensor to the outside through communications is employed because it is difficult to lead a line to the outside of the wafer. Further, such a configuration using the flexible substrate may also be advantageous in that multi-layering of lines within the flexible substrate can be achieved with an increase of measurement positions. Further, in Patent Document 1, a controller that occupies a very limited area on a semiconductor wafer is coated with a protective film made of a polyimide resin, and, thus, the controller has improved durability against plasma.

Here, the flexible substrate included in the temperature detecting unit is mounted on a wafer for temperature detection (hereinafter, referred to as a temperature detection wafer). In this configuration, when a temperature of the temperature detection wafer is changed, the following problems may occur. By way of example, a processing temperature may be varied depending on the required process content in an actual process. In consideration of such a case, the temperature detection wafer having the same shape as a wafer to be actually processed is heated by the temperature control unit provided within the mounting table. At this time, as temperature varies, the temperature detection wafer and the flexible substrate are deformed. Since the flexible substrate occupies a certain area on the temperature detection wafer, the temperature detection wafer having thereon the flexible substrate may be bent in one direction or another direction. That is, the semiconductor wafer disclosed in Patent Document 1, which has the controller occupying the very limited area on the semiconductor wafer and coated with the protective film, may be bent.

It is not desirable that the temperature detection wafer having the same shape as the wafer to be actually processed has such a problem. That is, if the temperature detection wafer is bent, the distance between a surface of the mounting table and a surface of the temperature detection wafer may be different at respective positions on the temperature detection wafer. Thus, it is concerned that the temperature detection wafer may not be uniformly heated at each position thereof. If the temperature detection wafer held on the mounting table could not be heated accurately, it is concerned that accurate temperature detection in the surface of the temperature detection wafer may not be carried out.

That is, if a temperature of a wafer, on which a semiconductor device is to be actually formed, is adjusted based on a detection result of the above-described wafer-type temperature sensor and a certain process is performed on the wafer, a temperature difference may be generated in the surface of the wafer, which is not provided with a circuit board and on which a semiconductor device is to be formed, when the process is performed. To elaborate, if the wafer-type temperature sensor, which assumes that bending has not occurred even though bending has actually occurred, outputs a result that a temperature of a central area is higher than a temperature of a periphery area, heating may be performed so as to increase the temperature of the periphery area rather than the temperature of the central area by the temperature control in the mounting table, and, then, the process may be performed. However, bending does not actually occur in the semiconductor wafer on which a semiconductor device is to be formed because no circuit board is formed thereon. Accordingly, the periphery area of the wafer may be over-heated by the mounting table, so that the temperature of the periphery area of the wafer may become increased too much. Accordingly, when a semiconductor device is formed, process uniformity in the surface of the wafer may be deteriorated. In this case, accurate temperature detection needs to be performed in the surface of the temperature detection wafer.

### BRIEF SUMMARY OF THE INVENTION

In view of the foregoing, the present disclosure provides a wafer-type temperature sensor capable of more accurately detecting a temperature in a surface of a wafer for temperature detection.

The present disclosure also provides a manufacturing method of a wafer-type temperature sensor capable of more accurately detecting a temperature in a surface of a wafer for temperature detection.

In accordance with one aspect of the present disclosure, there is provided a wafer-type temperature sensor including: a wafer for temperature detection; a circuit board bonded to one surface of the wafer for temperature detection; at least one temperature data detector provided on the one surface of the wafer for temperature detection and capable of detecting temperature data; and a temperature detecting unit mounted on the circuit board and capable of detecting a temperature of the wafer for temperature detection from the temperature data detected by the temperature data detector. Here, a difference between a linear expansion coefficient of the circuit board and a linear expansion coefficient of the wafer for temperature detection may be equal to or less than a predetermined value.

In accordance with the wafer-type temperature sensor, since the linear expansion coefficient of the circuit board is substantially equivalent or analogous to the linear expansion coefficient of the temperature detection wafer, when there is a change in the temperature of the temperature detection wafer due to, e.g., heating of the temperature detection wafer, the circuit board may also be deformed according to the deformation of the temperature detection wafer which is deformed due to such a change in the temperature. In this case, bending of the temperature detection wafer can be suppressed when temperature varies, so that it becomes possible to perform uniform heating at each position of the temperature detection wafer, as in the case of a wafer to be actually processed. Accordingly, the temperature of the temperature detection wafer can be detected more accurately.

Desirably, the circuit board may be bonded to the wafer by thermocompression. If the thermocompression is performed at a temperature as close to an actual processing temperature as possible, influence from bending of the temperature detection wafer may be reduced. Accordingly, the temperature in the surface of the temperature detection wafer can be detected more accurately.

The circuit board may be made of a polyimide-based resin, and the wafer for temperature detection may be made of at least one selected from a group consisting of silicon, ceramics, sapphire and glass.

Further, the difference between the linear expansion coefficients of the circuit board and the wafer may be equal to or less than about 5 ppm/° C. (parts per million/° C.).

More desirably, the at least one temperature data detector may be plural in number, and the multiple number of temperature data detectors may be provided on the one surface of the wafer for temperature detection.

Further, the at least one temperature data detector may be provided on the circuit board. Furthermore, a conducting wire for connecting the at least one temperature data detector with the temperature detecting unit may be provided on the circuit board.

Further, the wafer-type temperature sensor may include a transmitter capable of transmitting the temperature of the wafer for temperature detection detected by the temperature detecting unit to the outside of the wafer for temperature detection.

In accordance with another aspect of the present disclosure, there is provided a manufacturing method of a wafer-type temperature sensor including a wafer for temperature detection; a circuit board bonded to one surface of the wafer for temperature detection; a temperature data detector provided on the one surface of the wafer for temperature detection and capable of detecting temperature data; and a temperature detecting unit mounted on the circuit board and capable of detecting a temperature of the wafer from the temperature data detected by the temperature data detector. Here, a difference between a linear expansion coefficient of the circuit board and a linear expansion coefficient of the wafer for temperature detection may be equal to or less than a predetermined value. The manufacturing method of a wafer-type temperature sensor includes bonding the circuit board to the wafer for temperature detection by thermally compressing the circuit board at a temperature substantially equivalent to a temperature required for a wafer process.

In accordance with this manufacturing method of the wafer-type temperature sensor, in the manufactured wafer-type temperature sensor, since the circuit board and the temperature detection sensor are thermally compressed and bonded to each other at the temperature required for the actual process, influence from bending due to a difference between their linear expansion coefficients can be minimized under a temperature condition required for the actual process. Thus, temperature detection can be performed while maintaining parallelism between a surface of the mounting table and a surface of the wafer-type temperature sensor. Accordingly, temperature detection during the actual process can be more accurately carried out.

In accordance with the wafer-type temperature sensor, since the linear expansion coefficient of the circuit board is substantially equivalent or analogous to the linear expansion coefficient of the temperature detection wafer, when there is a change in the temperature of the temperature detection wafer due to, e.g., heating of the temperature detection wafer, the circuit board may also be deformed according to the deformation of the temperature detection wafer which is deformed due to such a change in the temperature. In this case, bending of the temperature detection wafer can be suppressed when temperature varies, so that it becomes possible to perform uniform heating at each position of the temperature detection wafer, as in the case of a wafer to be actually processed. Accordingly, the temperature of the temperature detection wafer can be detected more accurately.

Further, in accordance with the manufacturing method of the wafer-type temperature sensor, in the manufactured wafer-type temperature sensor, since the circuit board and the temperature detection sensor are thermally compressed and bonded to each other at the temperature required for the actual process, influence from bending due to a difference between their linear expansion coefficients can be minimized under a temperature condition required for the actual process. Thus, temperature detection can be performed while maintaining parallelism between a surface of the mounting table and a surface of the wafer-type temperature sensor. Accordingly, temperature detection during the actual process can be carried out more accurately.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a schematic cross sectional view illustrating a part of a plasma processing apparatus capable of performing a process on a wafer;

FIG. 2 illustrates a wafer-type temperature sensor in accordance with an embodiment of the present disclosure, when viewed from a plate thickness direction;

FIG. 3 is a cross sectional view of a wafer for temperature detection which is illustrated to be bent in a rather exaggerated manner;

FIG. 4 is a diagram schematically illustrating a measurement position where a temperature of the wafer for temperature detection is measured;

FIG. 5 is a graph showing a relationship between temperature and time;

FIG. 6 is a graph showing a relationship between temperature and a gap;

FIG. 7 is a graph showing a relationship between a temperature difference and a gap; and

FIG. 8 illustrates a wafer-type temperature sensor in accordance with another embodiment of the present disclosure, when viewed from a plate thickness direction.

### DETAILED DESCRIPTION OF THE INVENTION

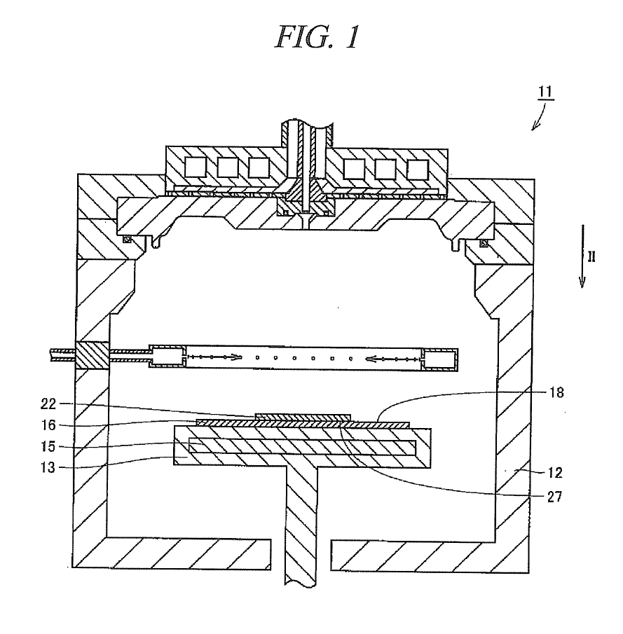

Hereinafter, embodiments of the present disclosure will be described with reference to the accompanying drawings. First, a plasma processing apparatus configured to perform a plasma process on a wafer will be first explained briefly. FIG. 1 is a schematic cross sectional view illustrating an example plasma processing apparatus that performs a plasma process on a wafer. In FIG. 1, a plasma processing apparatus 11 is a microwave plasma processing apparatus using a microwave as a plasma source. The plasma processing apparatus 11 is capable of accommodating therein a wafer to be actually processed, i.e., a wafer on which a semiconductor device or the like will be formed. The plasma processing apparatus 11 includes a processing chamber 12 configured to perform therein a plasma process on the wafer; and a mounting table 13 configured to hold thereon the wafer within the processing chamber 12. The wafer may be held on the mounting table 13 by using a vacuum chuck, an electrostatic chuck, a mechanical clamp or the like. The wafer has a size of, e.g., about φ300 mm. Further, in FIG. 1, for the simplicity of illustration, a wafer 16 for temperature detection is mounted on the mounting tale 13. By way of example, the wafer 16 for temperature detection is made of the same material as that of the wafer to be actually processed and has the same shape (size and thickness) as that of the wafer to be actually processed.

In an actual process, a plasma processing gas is supplied into the processing chamber 12 after the inside of the processing chamber 1 is depressurized to a preset pressure, and an etching process, a CVD process or the like is performed on a wafer held on the mounting table 14 by plasma generated within the processing chamber 12. Here, such a process is performed after a temperature of the wafer is adjusted to an appropriate temperature for the process by a temperature control unit 15 provided within the mounting table 13. To elaborate, the temperature control unit 15 may include, e.g., coolants or heaters provided in a central area and a periphery area within the mounting table 13, and it is possible to independently control temperatures of the central area and the periphery area of the mounting table 13. To be specific, before a target process is performed, heating or cooling of the mounting table 13 is performed by the temperature control unit 15 and the temperature of the wafer on the mounting table 13 is adjusted. In this way, the process can be performed more efficiently while achieving, e.g., process uniformity in the surface of the wafer.

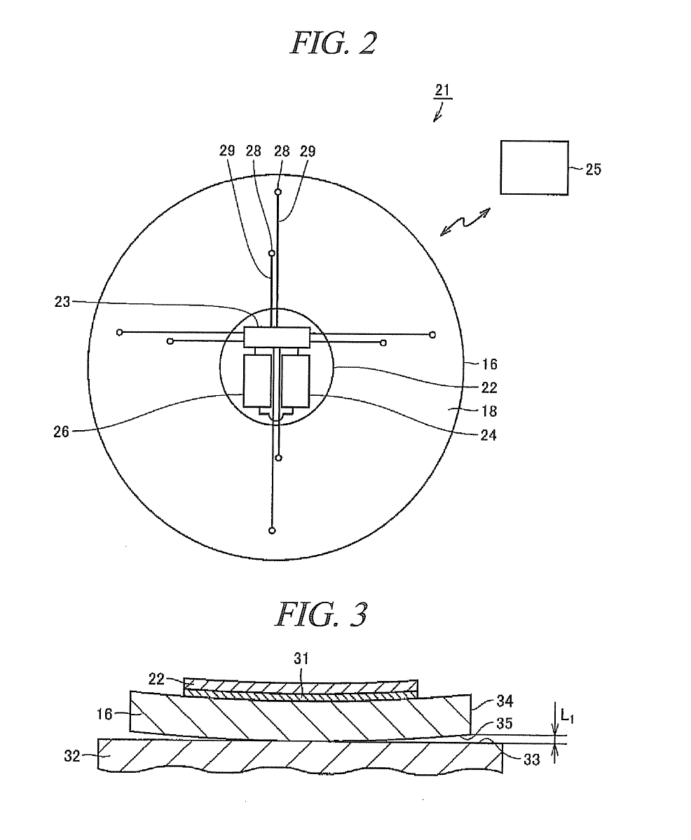

Now, a configuration of a wafer-type temperature sensor in accordance with an embodiment of the present disclosure will be elaborated. FIG. 2 provides an exterior view schematically illustrating the wafer-type temperature sensor in accordance with the embodiment of the present disclosure. FIG. 2 shows a diagram viewed from a direction of an arrow II in FIG. 1. That is, FIG. 2 is a diagram showing a circuit board to be described later when viewed from a plate thickness direction of the wafer 16 for temperature detection.

Referring to FIGS. 1 and 2, the wafer-type temperature sensor 21 in accordance with the present embodiment may include a circular plate-shaped wafer 16 for temperature detection (hereinafter, referred to as a temperature detection wafer 16); a circular plate-shaped circuit board 22 provided on a top surface 18 which is one surface of the temperature detection wafer 16 in a plate thickness direction; a temperature detecting unit 23 mounted on the circuit board 22 and serving as a temperature detecting mechanism for detecting a temperature at each position on the top surface 18 of the temperature detection wafer 16; a wafer data communication unit 24 mounted on the circuit board 22 and capable of communicating with the outside unit of the temperature detection wafer 16; and an external data communication unit 25 provided outside the temperature detection wafer 16 so as to be distanced apart from the temperature detection wafer 16 and capable of communicating with the wafer data communication unit 24. The external data communication unit 25 is provided outside the processing chamber 12 in FIG. 1. The wafer data communication unit 24 and the external data communication unit 25 are capable of transceiving data therebetween. That is, the wafer data communication unit 24 and the external data communication unit 25 are capable of performing wireless communications therebetween. Here, the wafer data communication unit 24 serves as a transmitting unit capable of transmitting temperature data of the temperature detection wafer 16 detected by the temperature detecting unit 23 to the outside of the temperature detection wafer 16. Formed on the circuit board 22 is a circuit that includes the temperature detecting unit 23 and the wafer data communication unit 24 as a part thereof, and a control unit 26 for controlling the entire circuit is also provided on the circuit board 22. The circuit board 26 may be a flexible substrate having high flexibility. Although an amplifier, a processor, a memory, a power supply or the like that constitutes the circuit may be further provided on the circuit board 22, their illustration is omitted herein for the simplicity.

The circuit board 22 is provided on a central area of the circular plate-shaped temperature detection wafer 16. Further, as can be clearly seen from FIG. 2, the circuit board 22 also has a circular plate shape and has a diameter equivalent to about ⅓ of a diameter of the temperature detection wafer. The circuit board 22 is bonded to the temperature detection wafer 16. To be more specific, the circuit board 22's bottom surface 27 facing the temperature detection wafer 16 is thermally compressed and bonded to the temperature detection wafer 16's top surface 18 facing the circuit board 22. A temperature for the thermocompression may be set to be about 120° C. as one of temperatures close to an actual processing temperature.

The temperature detecting unit 23 is provided with temperature data detectors 28 via conducting wires 29. The temperature data detectors 28 are embedded at different positions in the top surface 18 of the temperature detection wafer 16 and capable of detecting temperature data at each position. Further, as can be clearly seen from FIG. 2, the number of the temperature data detectors 28 is more than one. The temperature data at each position of the temperature detection wafer 16 detected by each temperature data detectors 28 is input to the temperature detecting unit 23 via the conducting wire 29. The input temperature data at each position is transmitted to the external data communication unit 25 by the wafer data communication unit 24. In this way, a temperature at each position in the surface of the temperature detection wafer 16 can be sent to the outside of the temperature detection wafer 16 accurately.

Here, it is desirable that a difference between a linear expansion coefficient of the circuit board and a linear expansion coefficient of the wafer for temperature detection is equal to or less than a predetermined value. For example, the temperature detection wafer 16 and the circuit board 22 may have substantially equivalent or analogous linear expansion coefficients, i.e., thermal expansion coefficients. Here, the linear expansion coefficient of the circuit board 22 refers to a linear expansion coefficient of an entire circuit board 22. To be specific, the temperature detection wafer 16 may be made of silicon Si having a linear expansion coefficient ranging from about 2.6 ppm/° C. to about 3.5 ppm/° C. The circuit board may be made of a polyimide resin having a linear expansion coefficient of about 3.5 ppm/° C.

In the wafer-type temperature sensor having the above-described configuration, since the linear expansion coefficient of the circuit board 22 is substantially equivalent or analogous to the linear expansion coefficient of the temperature detection wafer 16, when there is a change in the temperature of the temperature detection wafer 16 due to, e.g., heating of the temperature detection wafer 16, the circuit board may also be deformed according to the deformation of the temperature detection wafer 16 which is deformed due to such a change in the temperature. In this case, bending of the temperature detection wafer 16 can be suppressed when temperature varies, so that it becomes possible to perform uniform heating at each position of the temperature detection wafer 16, as in the case of a wafer to be actually processed. Accordingly, the temperature of the temperature detection wafer 16 can be more accurately detected.

Furthermore, as mentioned, the circuit board and the temperature detection wafer are bonded to each other by thermocompression. Here, since bending may occur at the temperature of thermocompression as a starting point, influence from bending of the temperature detection wafer may be reduced by performing the thermocompression at a temperature as close to an actual processing temperature as possible. That is, the manufacturing method in accordance with the embodiment of the present disclosure may provide a method for manufacturing a wafer-type temperature sensor including a wafer for temperature detection; a circuit board bonded to one surface of the wafer for temperature detection; a temperature data detector provided on the one surface of the wafer for temperature detection and capable of detecting temperature data; and a temperature detecting unit mounted on the circuit board and capable of detecting a temperature of the wafer from the temperature data detected by the temperature data detector. Here, a difference between a linear expansion coefficient of the circuit board and a linear expansion coefficient of the wafer for temperature detection is equal to or less than a predetermined value. The manufacturing method of the wafer-type temperature sensor may include bonding the circuit board to the wafer for temperature detection by thermally compressing the circuit board at a temperature substantially equivalent to a temperature required for a wafer process.

In accordance with this manufacturing method of the wafer-type temperature sensor, in the manufactured wafer-type temperature sensor, since the circuit board and the temperature detection sensor are thermally compressed and bonded to each other at the temperature required for the actual process, influence from bending due to a difference between their linear expansion coefficients can be minimized under a temperature condition required for the actual process. Thus, temperature detection can be performed while maintaining parallelism between a surface of the mounting table and a surface of the wafer-type temperature sensor. Accordingly, temperature detection during the actual process can be more accurately carried out. That is, even if the temperature detection wafer is slightly bent at a room temperature, the surface of the temperature detection wafer, i.e., its bottom surface facing the mounting table can be made, at the temperature close to the actual processing temperature, to be parallel to the surface of the mounting table, i.e., its top surface on which the temperature detection wafer is mounted. In order to achieve accurate temperature detection, it may be desirable that a processing table used for the thermocompression process has the same degree of flatness as that of the mounting table on which the wafer is mounted in the actual process. In this configuration, the temperature in the surface of the temperature detection wafer can be detected more accurately. That is, by setting the linear expansion coefficient of the circuit board to be substantially equivalent or analogous to the linear expansion coefficient of the temperature detection wafer and by performing the thermocompression of the circuit board and the temperature detection wafer at the temperature as close to the actual processing temperature as possible, heating and temperature detection of the temperature detection wafer at each position thereof can be performed while suppressing bending due to a minute difference between the linear expansion coefficients of the circuit board and the temperature detection wafer. Accordingly, accuracy of temperature detection at each position of the temperature detection wafer can be improved. To be specific, the thermocompression may be performed at, e.g., about 120° C. which is a temperature required for, e.g., an etching process as one of processes for forming a semiconductor device on a wafer to be actually processed.

### Experimental Example

A bending amount of a temperature detection wafer included in a wafer-type temperature sensor in accordance with the embodiment of the present disclosure is measured. FIG. 3 is a cross sectional view of the temperature detection wafer which is illustrated to be bent in a rather exaggerated manner. In FIG. 3, the temperature detection wafer having a size of about φ6 inches and made of silicon is used as a temperate detection wafer 16. A thickness of the temperature detection wafer 16 is about 625 μm. Further, a circuit board 22 having a size of about 85 mm×85 mm is used, and the temperature detection wafer 16 and the circuit board 22 are bonded to each other by thermocompression via an adhesive sheet 31 for thermocompression. After the circuit board 22 is thermally compressed and bonded to the temperature detection wafer 16, a bending amount of the temperature detection wafer on a table 32 is measured when a temperature is increased from a room temperature to about 200° C. A length L₁ from a top surface 33 of the table 32 to a bottom surface 35 at an edge 34 of the temperature detection wafer 16 is measured, and the length L₁ is defined as the bending amount.

Here, as a comparative example 1, a circuit board 22 configured as a rigid substrate made of a general-purpose glass epoxy-based resin having a thickness of about 1 mm is used; as a comparative example 2, a circuit board 22 configured as a flexible substrate made of a general purpose glass epoxy-based resin having a thickness of about 0.1 mm is used; as a comparative example 3, a circuit board 22 configured as a liquid polymer-based flexible substrate having a thickness equal to or less than about 50 μm is used; as an experimental example 1, a circuit board 22 configured as a flexible substrate made of a polyimide-based resin having a thickness equal to or less than about 50 μm is used. Linear expansion coefficients in these examples are specified in Table 1. Here, K denotes an absolute temperature, i.e., Kelvin.

TABLE 1

| | | | Liquid | Polyimide |
|---|---|---|---|---|
| | | | polymer- | resin- |
| | Silicon | Glass epoxy | based | based |
| | (Single | resin-based | flexible | flexible |
| Material | crystalline) | substrate | substrate | substrate |
| Linear expansion | 2.6 (293K) | About 15 in xy | 18 | 3.5 |
| coefficient | 3.5 (500K) | direction α1 | | |
| (ppm/K) | | About 65 in z | | |
| | | direction α1 | | |
| | | About 320 in z | | |
| | | direction α2 | | |

Referring to the Table 1, a linear expansion coefficient of the silicon is about 2.6 at 293 K and about 3.5 at 500 K. In comparison, a linear expansion coefficient of the glass epoxy-based resin ranges from about 15 to about 320 depending on directions. That is, the glass epoxy-based resin has a linear expansion coefficient single-digit or double-digit greater than that of the silicon. Further, the liquid polymer-based flexible substrate has a linear expansion coefficient of about 18, which is single-digit greater than that of the silicon. Meanwhile, the polyimide resin-based flexible substrate has a linear expansion coefficient of about 3.5 substantially equivalent or analogous to that of the silicon.

Bending amounts in the comparative examples 1 to 3 are about 5 mm, about 2 mm and about 1 mm, respectively. In contrast, a bending amount in the experimental example 1 is not greater than about 20 μm.

As can be seen from these examples, by setting the linear expansion coefficient of the temperature detection wafer 16 and the linear expansion coefficient of the circuit board 22 to be substantially equivalent or analogous to each other, the bending amount can be greatly reduced.

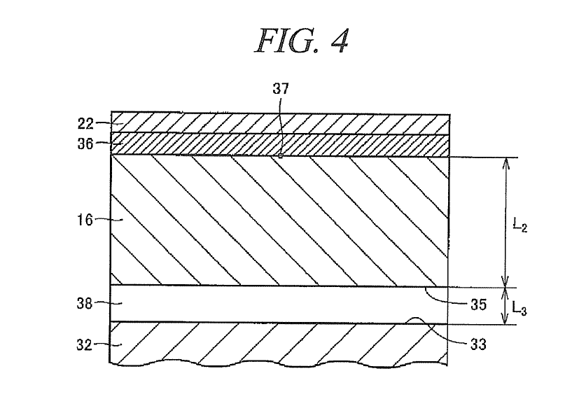

Now, a relationship between a gap generated by bending of the temperature detection wafer and a temperature characteristic of the temperature detection wafer will be explained. FIG. 4 schematically illustrates a measurement position where a temperature of the temperature detection wafer 16 is measured. Further, FIG. 4 shows an enlarged cross sectional view of the temperature detection wafer 16 of which a part is cut in a plate thickness direction. As shown in FIG. 4, the temperature detection wafer 16 made of silicon is provided at a position above the table 32, and the circuit board 22 is pressed on the temperature detection wafer 16 via a silicon oxide film 36. The temperature detection wafer 16 has a thickness of about 775 μm, and a position distanced upward from the bottom surface 35 of the temperature detection wafer 16 in the plate thickness direction is set as a temperature measurement position 37. That is, a length L₂ in FIG. 4 is about 775 μm.

A gap 38 is provided between the temperature detection wafer 16 and the table 32 that supplies heat, and it is assumed that the gap 38 has a physical property of atmosphere. In each case of setting the size of the gap 38, i.e., a length L₃ between a top surface 33 of the table 32 and the bottom surface 35 of the temperature detection wafer 16 to be about 100 μm and about 500 μm, a temperature is measured at the measurement position. A temperature of the table 32 is set to be about 130° C.

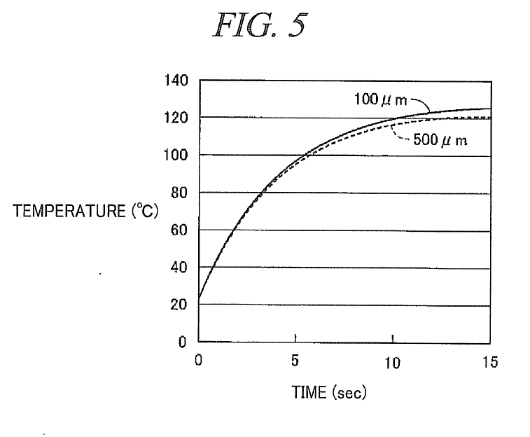

FIG. 5 is a graph showing a relationship between temperature and time. In FIG. 5, a vertical axis represents a temperature (° C.) at the measurement position, and a horizontal axis indicates time (sec). Referring to FIG. 5, when the gap is about 100 μm, the temperature at the measurement position already reaches about 120° C. after a lapse of about 10 seconds. On the other hand, when the gap is about 500 μm, the temperature at the measurement position is found to be about 115° C. even after the lapse of about 10 seconds. That is, after about 10 seconds elapses, a temperature difference of about 5° C. is generated between the two cases where the gap is about 100 μm and about 500 μm. Such a great difference may deteriorate uniformity in the wafer surface depending on, e.g., the content of a process involved.

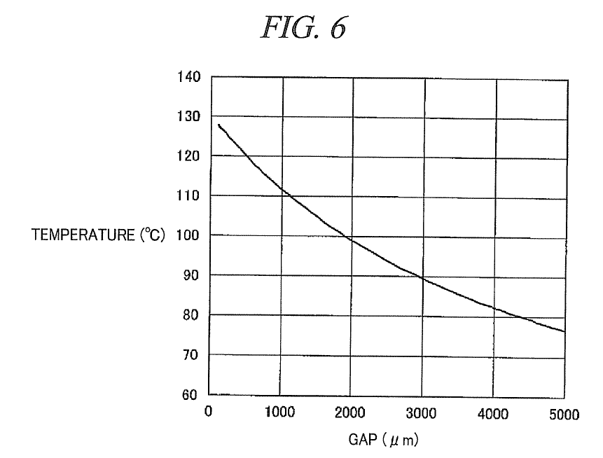

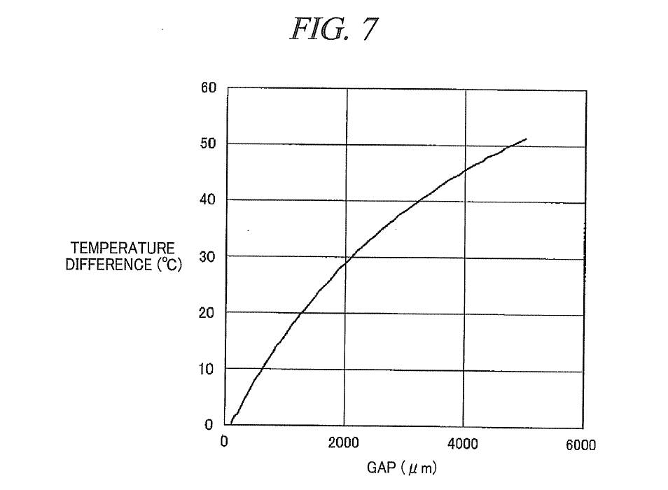

FIG. 6 is a graph showing a relationship between final temperature at the measurement position and a gap. In FIG. 6, a vertical axis represents a temperature (° C.) at the measurement position and a horizontal axis indicates a gap (μm). FIG. 7 is a graph showing a relationship between a temperature difference and a gap when a gap is about 100 μm. In FIG. 7, a vertical axis represents a temperature difference (° C.) at the measurement position, and a horizontal axis indicates a gap (μm). As depicted in FIGS. 6 and 7, in the experiment example 1 in which the bending amount is about 20 μm, the temperature at the measurement position is decreased by about 0.42° C. in case of the table of 130° C. However, in the comparative example 1 in which the bending amount is about 5 mm, since the temperature at the measurement position is lower than about 80° C., the temperature at the measurement position is decreased by about 51° C. as compared to a case of the experiment example 1. In this way, a great difference is found in their final temperatures in these two cases. Under actually required processing conditions, however, a temperature difference needs to be no greater than about 0.1° C. Even if a less strict requirement for the temperature difference is applied, the temperature difference needs to be no greater than about 2° C., desirably. Thus, such a gap difference of several hundreds of micrometers may have a great impact on the final temperature of the temperature detection wafer.

Further, in the above-described embodiment, although the temperature detection wafer is made of silicon, an example of using a temperature detection wafer made of a material other than silicon will now be explained. Ceramics (99.6% of alumina), sapphire, glass represented by quartz or the like may be used as a material for a temperature detection wafer, and their linear expansion coefficients are about 8.2 ppm/° C., 7.7 ppm/° C. and 0.6 ppm/° C., respectively. Depending on the linear expansion coefficients of these materials for the temperature detection wafer, a material having a linear expansion coefficient substantially equivalent or analogous to that of the temperature detection wafer may be selected for the circuit board. In such a case, it may be most desirable that the circuit board may be made of completely the same materials as that of the temperature detection wafer. However, since the linear expansion coefficients of the ceramics (99.6% of alumina), the sapphire and the glass are single-digit numbers, it may be also possible to use a polyimide resin having a single-digit linear expansion coefficient. By selecting such materials, a difference between linear expansion coefficients of the temperature detection wafer and the circuit board needs to be, e.g., equal to or less than about 5 ppm/° C. Furthermore, in the above embodiment, although the circuit board has been described to be made of a polyimide-based resin, the material for the circuit board may not be limited thereto, but a material having the substantially equivalent or analogous linear expansion coefficient may be used instead.

Moreover, in the above embodiment, although the circuit board and the wafer are bonded by thermocompression, the present disclosure may not be limited thereto. The circuit board and the wafer may be bonded to each other by other methods, e.g., by using an adhesive.

In addition, in the above-described embodiment, the circular plate-shaped circuit board has a diameter equivalent to about ⅓ of the diameter of the temperature detection wafer, and the temperature data detector is provided at each position of the temperature detection wafer. However, the present disclosure may not be limited thereto. By way of example, the circuit board may have the substantially same size as that of the temperature detection wafer, and the temperature data detector may be installed on the circuit board.

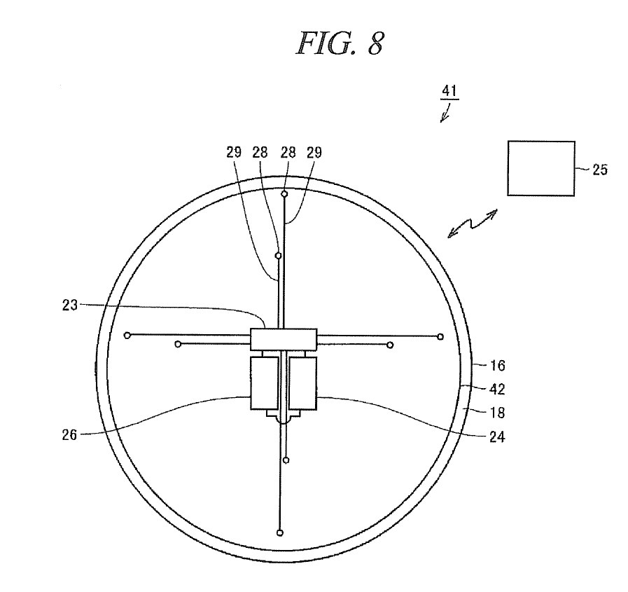

FIG. 8 illustrates a wafer-type temperature sensor and corresponds to FIG. 2. As for the description of the wafer-type temperature sensor of FIG. 8 in accordance with another embodiment of the present disclosure, the same parts as those of the water-type temperature sensor disclosed in FIG. 2 will be assigned same reference numerals, and redundant description thereof will be omitted.

Referring to FIG. 8, a wafer-type temperature sensor 41 in accordance with another embodiment of the present disclosure may include a circular plate-shaped circuit board 42. The circuit board 42 may have a diameter slightly smaller than that of a temperature detection wafer 16. Further, temperature data detectors 28 and conducting wires 29 may be installed on the circuit board 42.

In this configuration, since a temperature detecting unit 23, the temperature data detectors 28, the conducting wires 29 and so forth are installed on the circuit board 42, the parts that constitute the wafer-type temperature sensor 41 can be installed altogether on the single circuit board 42. Thus, the manufacture of the water-type temperature sensor 41 can be facilitated and this configuration may be cost-effective. Further, as illustrated in FIG. 8, if the size of the circuit board 42 is relatively large, a contact area between the circuit board 42 and the temperature detection wafer 16 may be also enlarged. Here, although influence of bending caused by a difference in linear expansion coefficients tends to be enhanced with the increase of the contact area, such influence of bending can be reduced greatly in accordance with the present disclosure. That is, the configuration as illustrated in FIG. 8 may still have great effects in accordance with the present disclosure.

Further, as for the multiple number of temperature data detectors 28 shown in the configurations of FIGS. 2 and 8, it may be also possible to provide a part of them on the circuit board 22 (42) and to provide the rest on the temperature detection wafer 16, not on the circuit board 22 (42). Furthermore, a configuration using only a single temperature data detector 28 may also be used.

Furthermore, in the above-described embodiments, although the circuit board is configured as a flexible substrate, the circuit board may be a rigid substrate without being limited thereto. In case that the circuit board is a rigid substrate, it may be desirable that the circuit board is as thin as possible to be deformed according to a deformation of the temperature detection wafer. By way of example, the circuit board as the rigid substrate may have a thickness of about 100 μm or less.

Further, in the above-described embodiments, the wafer data communication unit and the external data communication unit perform wireless communications therebetween, the present disclosure may not be limited thereto, and they may perform wire communications. Furthermore, temperatures of the temperature detection wafer detected by the temperature detecting unit may be stored in a memory or the like, and the temperature of the temperature detection wafer may be read out from the memory when the temperature detection wafer is taken out of the processing chamber.

Further, the above-described wafer-type temperature sensor may be used in a plasma processing apparatus using parallel plate type plasma, ICP (Inductively-Coupled Plasma), ECR (Electron Cyclotron Resonance) plasma, or the like as well as in the above-mentioned plasma processing apparatus using the microwave as a plasma source. Further, the wafer-type temperature sensor may also be applied to other semiconductor manufacturing processes without using plasma, such as a photolithography process, a thermal oxidizing process in a thermal oxidation furnace, a wafer transferring process, or the like. That is, in a temperature management of a wafer during a photolithography process, for example, accurate temperature detection can be carried out using the wafer-type temperature sensor having the above-described configuration. While various aspects and embodiments have been described herein, other aspects and embodiments will be apparent to those skilled in the art. The various aspects and embodiments disclosed herein are for the purposes of illustration and are not intended to be limiting. Therefore, the true scope of the disclosure is indicated by the appended claims rather than by the foregoing description, and it shall be understood that all modifications and embodiments conceived from the meaning and scope of the claims and their equivalents are included in the scope of the disclosure.

What is claimed is:

1. A wafer-type temperature sensor comprising:
a wafer for temperature detection;
a circuit board bonded to one surface of the wafer for temperature detection;
at least one temperature data detector provided on the one surface of the wafer for temperature detection and capable of detecting temperature data; and
a temperature detecting unit mounted on the circuit board and capable of detecting a temperature of the wafer for temperature detection from the temperature data detected by the temperature data detector,
wherein a difference between a linear expansion coefficient of the circuit board and a linear expansion coefficient of the wafer for temperature detection is equal to or less than a predetermined value.

2. The wafer-type temperature sensor of claim 1, wherein the circuit board is bonded to the wafer by thermocompression.

3. The wafer-type temperature sensor of claim 1, wherein the circuit board is a flexible substrate.

4. The wafer-type temperature sensor of claim 1, wherein the at least one temperature data detector is plural in number, and the plurality of temperature data detectors are provided on the one surface of the wafer for temperature detection.

5. The wafer-type temperature sensor of claim 1, wherein the at least one temperature data detector is provided on the circuit board.

6. The wafer-type temperature sensor of claim 5, wherein a conducting wire for connecting the at least one temperature data detector with the temperature detecting unit is provided on the circuit board.

7. The wafer-type temperature sensor of claim 1, further comprising:
a transmitter capable of transmitting the temperature of the wafer for temperature detection detected by the temperature detecting unit to the outside of the wafer for temperature detection.

8. The wafer-type temperature sensor of claim 1, wherein the circuit board is made of a polyimide-based resin, and
the wafer for temperature detection is made of at least one selected from a group consisting of silicon, ceramics, sapphire and glass.

9. The wafer-type temperature sensor of claim 1, wherein the difference between the linear expansion coefficients of the circuit board and the wafer is equal to or less than about 5 ppm/° C.

10. A manufacturing method of a wafer-type temperature sensor including a wafer for temperature detection; a circuit board bonded to one surface of the wafer for temperature detection; a temperature data detector provided on the one surface of the wafer for temperature detection and capable of detecting temperature data; and a temperature detecting unit mounted on the circuit board and capable of detecting a temperature of the wafer from the temperature data detected by the temperature data detector, the method comprising:
bonding the circuit board to the wafer for temperature detection by thermally compressing the circuit board at a temperature substantially equivalent to a temperature required for a wafer process,
wherein a difference between a linear expansion coefficient of the circuit board and a linear expansion coefficient of the wafer for temperature detection is equal to or less than a predetermined value.
